(19) United States
(12) Patent Application Publication
(10) Pub. No.: US 2008/0054394 A1
(43) Pub. Date: Mar. 6, 2008

(54) RESISTANCE TYPE MEMORY DEVICE

(75) Inventors: Cha-Hsin Lin, Tainan City (TW); Ching-Chiun Wang, Miaoli County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: INDUSTRIAL TECHNOLOGY RESEARCH INSTITUTE, Hsinchu (TW)

(21) Appl. No.: 11/554,591

(22) Filed: Oct. 31, 2006

(30) Foreign Application Priority Data
Sep. 4, 2006 (TW) 95132536

(51) Int. Cl. H01L 29/00

(52) U.S. Cl. 257/529

(57) ABSTRACT

A resistance type memory device disposed on a substrate including a first conductive layer, a second conductive layer and a variable resistance material layer is described. These conductive layers are composed of single or separate electrodes. The variable resistance material layer is disposed between the first conductive layer and the second conductive layer.

### CROSS-REFERENCE TO RELATED APPLICATION

This application claims the priority benefit of Taiwan application serial no. 95132536, filed Sep. 4, 2006. All disclosure of the Taiwan application is incorporated herein by reference.

### BACKGROUND OF THE INVENTION

1. Field of the Invention

The present invention relates to a memory device, and more particularly, to a resistance type memory device.

2. Description of Related Art

With the rapid advance in communication technologies and the world wide web, the need for data exchange and processing are highly demanded. In particular, there is a big demand for quickly transmitting a large volume of audio/video data. On the other hand, in the present global competition, the work environment is no longer confined to an office environment, employees may have to work from another place or another part of the world. Under such circumstances, a large quantity of data is often required to support a particular action or decision. As a result, portable digital apparatus such as notebook (NB) computer, personal digital assistant (PDA), mobile phone, digital camera (DC) have become the ‘mobile platform’ and the demand for these portable digital apparatus are increased substantially. Correspondingly, the demand for the storage devices used inside the aforementioned digital products is also increase significantly.

Beginning from 1990, memories developed using the semiconductor storage technology have already become a new technology in the existing storage media. To correspond to the increasing demand for memory due to the need to store or transmit large volumes of data, the development of new types of memory devices is both meaningful and worthwhile.

### SUMMARY OF THE INVENTION

The present invention provides a resistance type memory device capable of performing a single storage point multi-bit storage process.

The present invention further provides a resistance type memory device that can be used in both volatile memory and non-volatile memory.

The present invention further provides a resistance type memory device whose manufacturing process can be integrated with the existing processes.

As embodied and broadly described herein, the present invention provides a resistance type memory device disposed on a substrate. The resistance type memory device includes a first conductive layer, a second conductive layer and a variable resistance material layer. The second conductive layer is disposed over the first conductive layer and composed of separate electrodes. The variable resistance material layer is disposed between the first conductive layer and the second conductive layer.

The present invention also provides another resistance type memory device disposed on a substrate. The resistance type memory device includes a first conductive layer, a second conductive layer and a variable resistance material layer. The first conductive layer is composed of separate electrodes. The second conductive layer is disposed over the first conductive layer. The variable resistance material layer is disposed between the first conductive layer and the second conductive layer.

The present invention also provides yet another resistance type memory device disposed on a substrate. The resistance type memory device includes a first conductive layer, a second conductive layer and a variable resistance material layer. The first conductive layer is composed of a plurality of first electrodes. The second conductive layer is disposed over the first conductive layer and composed of a plurality of second electrodes. The variable resistance material layer is disposed between the first conductive layer and the second conductive layer.

Based on the foregoing description, the resistance type memory device in the present invention is a novel memory device. The resistance type memory device of the present invention stores data by using the separate electrodes to produce different values of resistance in the variable resistance material layer. Therefore, the goal of storing multiple bits in a single storage point can be realized.

In addition, the resistance type memory device of the present invention can be applied to volatile memory as well as non-volatile memory.

Furthermore, the resistance type memory device of the present invention can be fabricated by designing a photomask pattern. Hence, the manufacturing of the resistance type memory device can be integrated with the existing processes.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a resistance type memory device according to a first embodiment of the present invention.

FIGS. 2A through 2D are schematic cross-sectional views showing the operation of the resistance type memory device in FIG. 1.

FIG. 3 is a schematic cross-sectional view of a resistance type memory device according to a second embodiment of the present invention.

FIG. 4 is a schematic cross-sectional view of a resistance type memory device according to a third embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

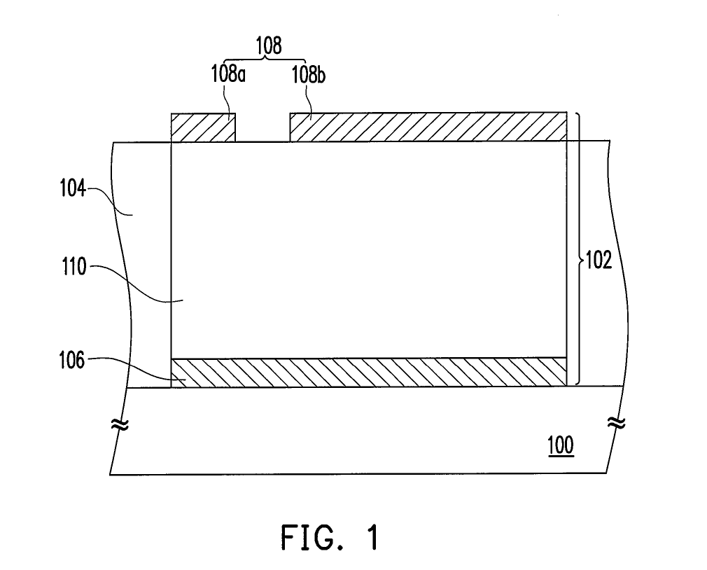

FIG. 1 is a schematic cross-sectional view of a resistance type memory device according to a first embodiment of the present invention.

As shown in FIG. 1, the resistance type memory device 102 is disposed on a substrate 100. Furthermore, a portion of the resistance type memory device 102 is, for example, disposed within a dielectric layer 104 on the substrate 100. The substrate 100 may be comprised of a silicon substrate and the dielectric layer 104 may be comprised of a silicon oxide, for example.

The resistance type memory device 102 includes a conductive layer 106, a conductive layer 108 and a variable resistance material layer 110.

The conductive layer 106 is disposed on the substrate 100 and serves as a single electrode. The material constituting the conductive layer 106 includes a semiconductor material such as doped polysilicon, a metallic material such as aluminum or copper or a metallic compound material such as titanium nitride. The conductive layer 106 may be formed by, for example, performing a chemical vapor deposition process or a physical vapor deposition process.

The conductive layer 108 is disposed over the conductive layer 106 and composed of a plurality of electrodes, that is, separate electrodes 108a and 108b. The material constituting the conductive layer 108 includes a semiconductor material such as doped polysilicon, a metallic material such as aluminum or copper or a metallic compound material such as titanium nitride. The conductive layer 108 may be formed by, for example, performing a chemical vapor deposition process or a physical vapor deposition process. The electrodes 108a and 108b have different sizes, for example, with the width of the electrode 108a smaller than that of the electrode 108b.

The variable resistance material layer 110 is disposed between the conductive layer 106 and the conductive layer 108. The variable resistance material layer 110 is fabricated using a material, for example, hafnium oxide or titanium oxide, whose resistance value can be changed through the application of a voltage or a current. The variable resistance material layer 110 may be formed by, for example, performing a chemical vapor deposition process.

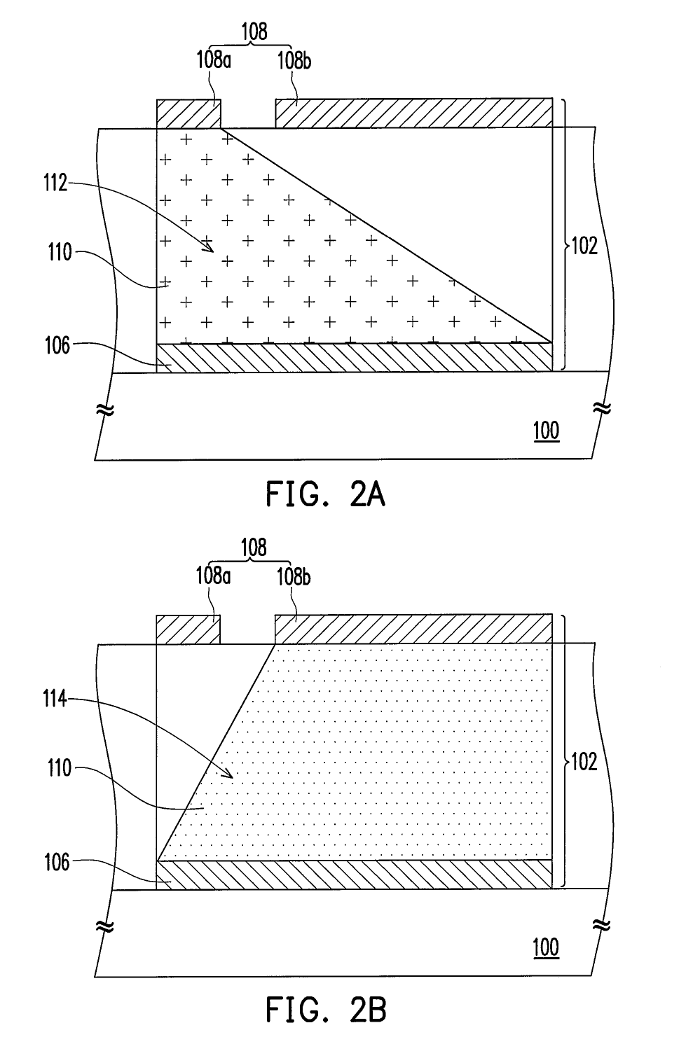

FIGS. 2A through 2D are schematic cross-sectional views showing the operation of the resistance type memory device in FIG. 1.

As shown in FIG. 2A, voltages may be applied to the conductive layer 106 and the electrode 108a to program the resistance type memory device 102. With the application of the voltages, a current will flow across an area 112 of the variable resistance material layer 110 so that the resistance in this area 112 is changed. Then, the data is read using the conductive layer 106, the electrodes 108a and 108b. Due to the change in the resistance in the area 112, the data storage state of the memory may be judged as a first storage state (1, 0) according to the resistance between the conductive layer 106 and the conductive layer 108.

As shown in FIG. 2B, voltages may be applied to the conductive layer 106 and the electrode 108b to program the resistance type memory device 102. With the application of the voltages, a current will flow across an area 114 of the variable resistance material layer 110 so that the resistance in this area 114 is changed. Then, the data is read using the conductive layer 106 and the electrodes 108a and 108b. Due to the change in the resistance in the area 114, the data storage state of the memory may be judged as a second storage state (0, 1) according to the resistance between the conductive layer 106 and the conductive layer 108.

As shown in FIG. 2C, voltages may be applied to the conductive layer 106, the electrode 108a and the electrode 108b to program the resistance type memory device 102. With the application of the voltages, currents will flow across areas 112 and 114 of the variable resistance material layer 110 so that the resistance in these areas 112 and 114 are changed. Then, the data is read using the conductive layer 106 and the electrodes 108a and 108b. Due to the changes in the resistance in both areas 112 and 114, the data storage state of the memory may be judged as a third storage state (1, 1) according to the resistance between the conductive layer 106 and the conductive layer 108.

As shown in FIG. 2D, the resistance of the variable resistance material layer 110 is unchanged before the resistance type memory device 102 is programmed. When data is subsequently read using the conductive layer 106 and the electrodes 108a and 108b, because the resistance in both areas 112 and 114 remain unchanged, the data storage state of the memory may be judged as a fourth storage state (0, 0) according to the resistance between the conductive layer 106 and the conductive layer 108.

It should be noted that the electrodes 108a and 108b are regarded as one and the same electrode in a reading operation due to their identical potential but regarded as independent electrodes in a programming operation.

Because the width of the electrode 108a is smaller than that of the electrode 108b as shown in FIGS. 2A through 2D, this affects the surface area in the variable resistance material layer 110 so that the area 112 is smaller than the area 114. Since the size of the resistance is related to the size of the area having a change in resistance, four different resistance values can be read as illustrated in FIGS. 2A through 2D, which represent the four different data storage states (1, 0), (0, 1), (1, 1) and (0, 0).

Accordingly, the resistance type memory device 102 of the present invention stores data by using the separate electrodes 108a and 108b to produce different values of resistance in the variable resistance material layer 110. Therefore, multiple bits of data can be stored in a single storage point.

In addition, the resistance type memory device 102 of the present invention can be applied to volatile memory as well as non-volatile memory.

Furthermore, the resistance type memory device 102 of the present invention can be easily fabricated by designing a photomask pattern. Hence, the manufacturing of the resistance type memory device can be integrated with the existing processes.

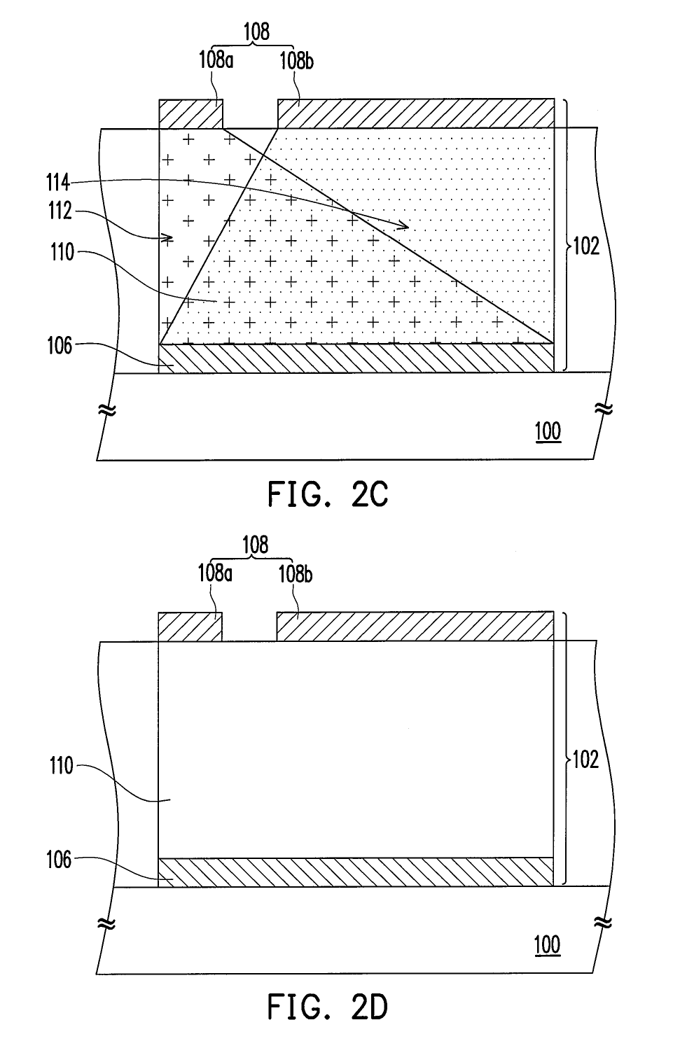

FIG. 3 is a schematic cross-sectional view of a resistance type memory device according to a second embodiment of the present invention.

As shown in FIGS. 1 and 3, the resistance type memory device 202 in FIG. 3 and the resistance type memory device 102 in FIG. 1 are very similar. The main difference is that the conductive layer 106 of the resistance type memory device 102 is a single electrode but the conductive layer 106 in the resistance type memory device 202 is composed of separate electrodes (the electrode 106a and the electrode 106b). On the other hand, the conductive layer 108 in the resistance type memory device 102 is composed of separate electrodes (the electrode 108a and the electrode 108b), but the conductive layer 108 of the resistance type memory device 202 is a single electrode. The electrodes 106a and 106b in the resistance type memory device 202 have different sizes, for example, with the width of the electrode 106a greater than that of the electrode 106b. Since the method of operating the resistance type memory device 202 and the materials in FIG. 3, disposition and manufacturing method of the components are similar to the resistance type memory device 102 in FIG. 1, a detailed description thereof is omitted.

Although the structure of the resistance type memory device 202 is slightly different from the resistance type memory device 102, the separate electrodes 106a and 106b are similarly capable of producing different resistance in the variable resistance material layer 110. Therefore, multiple bits of data may be stored in a single storage point.

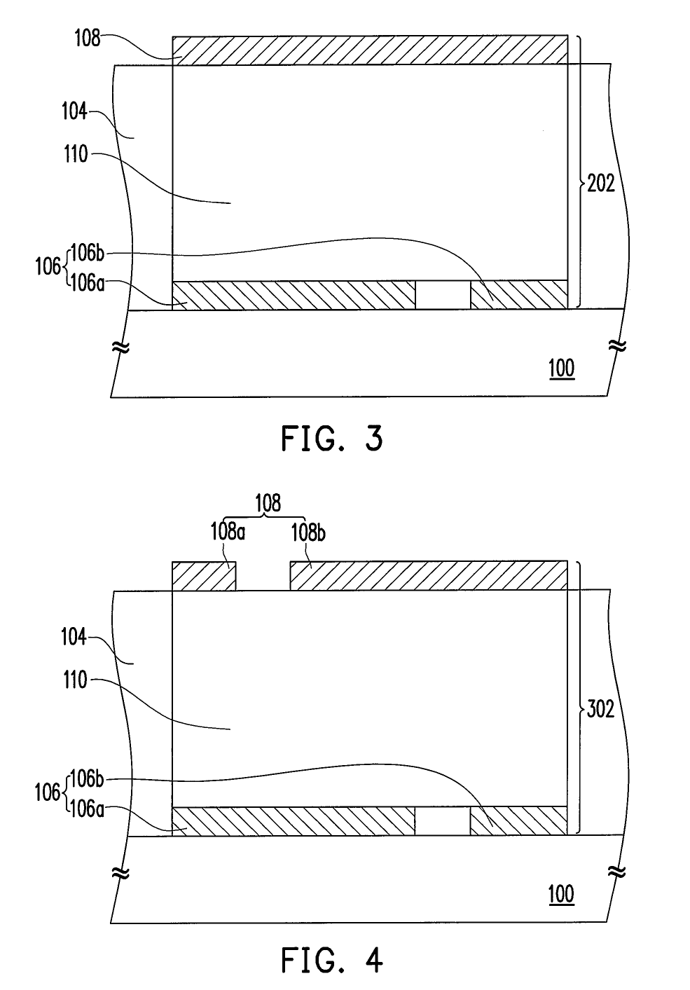

FIG. 4 is a schematic cross-sectional view of a resistance type memory device according to a third embodiment of the present invention.

As shown in FIGS. 1 and 4, the resistance type memory device 302 in FIG. 4 and the resistance type memory device 102 in FIG. 1 are very similar. The main difference is that while the conductive layer 106 of the resistance type memory device 102 is a single electrode and the conductive layer 108 is composed of separate electrodes (the electrodes 108a and 108b), but both the conductive layer 106 and the conductive layer 108 of the resistance type memory device 302 are composed of separate electrodes (the conductive layer 106 composed of the electrodes 106a and 106b, and the conductive layer 108 composed of the electrodes 108a and 108b). The electrode 106a and the electrode 106b in the resistance type memory device 302 have different sizes, for example, with the width of the electrode 106a greater than that of the electrode 106b. In a similar way, the electrodes 108a and 108b in the resistance type memory device 302 have different sizes, for example, with the width of the electrode 108a smaller than that of the electrode 108b. Since the method of operating the resistance type memory device 302 and the materials, disposition and manufacturing method of the components in FIG. 4 are similar to the resistance type memory device 102 in FIG. 1, a detailed description thereof is omitted.

Although the structure of the resistance type memory device 302 is slightly different from the resistance type memory device 102, the separate electrodes 106a and 106b and the separate electrodes 108a and 108b are similarly capable of producing different resistance in the variable resistance material layer 110. Consequently, multiple bits of data can be stored in a single storage point.

It should be noted that the resistance type memory device in the foregoing embodiments are shown to be composed of at most two electrodes when the conductive layer 106 and the conductive layer 108 are respectively composed of separate electrodes. The number of electrodes constituting the conductive layers 106 and 108 is not limited to only two, each of the conductive layers 106 and 108 may be comprised of more than two electrodes. In fact, those skilled in the art can modify the design of the memory device. In addition, the widths of the conductive layer 106 and the conductive layer 108 of the resistance type memory device and the widths of the electrodes constituting the conductive layers 106 and 108 may also be adjusted according to the design of the memory device.

In summary, the present invention has at least the following advantages.

1. The resistance type memory device is capable of storing multiple bits in a single storage point.

2. The resistance type memory device can be applied to both volatile memory and non-volatile memory.

3. The resistance type memory device can be fabricated by designing a photomask pattern so that its manufacturing process thereof can be integrated with the existing processes.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A resistance type memory device, disposed on a substrate, comprising:
a first conductive layer;
a second conductive layer, disposed over the first conductive layer and composed of a plurality of separate electrodes; and
a variable resistance material layer, disposed between the first conductive layer and the second conductive layer.

2. The resistance type memory device of claim 1, wherein widths of the separate electrodes are different.

3. The resistance type memory device of claim 1, wherein the variable resistance material layer comprises hafnium oxide or titanium oxide.

4. The resistance type memory device of claim 1, wherein the first conductive layer comprises a semiconductor material, a metallic material or a metallic compound material.

5. The resistance type memory device of claim 1, wherein the second conductive layer comprises a semiconductor material, a metallic material or a metallic compound material.

6. A resistance type memory device, disposed on a substrate, comprising:
a first conductive layer, composed of a plurality of separate electrodes;
a second conductive layer, disposed over the first conductive layer; and
a variable resistance material layer, disposed between the first conductive layer and the second conductive layer.

7. The resistance type memory device of claim 6, wherein widths of the separate, electrodes are different.

8. The resistance type memory device of claim 6, wherein the variable resistance material layer comprises hafnium oxide or titanium oxide.

9. The resistance type memory device of claim 6, wherein the first conductive layer comprises a semiconductor material, a metallic material or a metallic compound material.

10. The resistance type memory device of claim 6, wherein the second conductive layer comprises a semiconductor material, a metallic material or a metallic compound material.

11. A resistance type memory device, disposed on a substrate, comprising:
a first conductive layer, composed of a plurality of separate first electrodes;
a second conductive layer, disposed over the first conductive layer and composed of a plurality of separate second electrodes; and
a variable resistance material layer, disposed between the first conductive layer and the second conductive layer.

12. The resistance type memory device of claim 11, wherein widths of the separate first electrodes are different.

13. The resistance type memory device of claim 11, wherein widths of the separate second electrodes are different.

14. The resistance type memory device of claim 11, wherein the variable resistance material layer comprises hafnium oxide or titanium oxide.

15. The resistance type memory device of claim 11, wherein the first conductive layer comprises a semiconductor material, a metallic material or a metallic compound material.

16. The resistance type memory device of claim 11, wherein the second conductive layer comprises a semiconductor material, a metallic material or a metallic compound material.
